(19) United States
(12) Patent Application Publication
(10) Pub. No.: US 2022/0404101 A1
(43) Pub. Date: Dec. 22, 2022

(54) HEAT DISSIPATION NET

(71) Applicant: MING-CHENG CHEN, Taichung City (TW)

(72) Inventor: MING-CHENG CHEN, Taichung City (TW)

(21) Appl. No.: 17/351,564

(22) Filed: Jun. 18, 2021

(51) Int. Cl. F28D 15/02; H05K 7/20

(52) U.S. Cl. CPC F28D 15/0233; H05K 7/20336; F28D 15/0275; F28D 2015/0216

(57) ABSTRACT

A heat dissipation net disposed on a base plate of a vapor chamber unit includes a base net portion and conduction units formed on the base net portion. Each conduction unit has a protruding area, a recessed area, and a curved section formed between the protruding area and the recessed area. When the heat dissipation net is disposed on the base plate, the existence of the recessed area and the curved section prevents the base net portion from being unduly pressed and stuck to the base plate to thereby improve a capillary action of the heat dissipation net. A space formed between each protruding area and the base plate facilitates the quick conduction of vaporized working fluid of the vapor chamber unit. Thus, the entire heat dissipation efficiency is increased.

### BACKGROUND OF THE INVENTION

### 1. Field of the Invention

This invention relates to a heat dissipation structure and relates particularly to a heat dissipation net adapted to be disposed on a vapor chamber unit and capable of facilitating quick heat dissipation.

### 2. Description of the Related Art

In recent years, the development of electronic products becomes more popular. Especially, electronic components installed in the electronic products are also improved to equip with various functions and allow the electronic components to have high working efficiency, light weight and minimized volume. While the electronic components are provided with minimized volume and improved functions, the electronic components are also requested to have high operating performance. However, high operating performance will cause a temperature of the electronic components rises speedily. Meanwhile, each electronic product usually contains a plurality of electronic components. The electronic components crowding in the electronic product will result in an increased calorific area of the electronic product. When the volume of the electronic product is minimized, a space formed inside the electronic product and adapted to accommodate the electronic components is also reduced, and that will cause that heat generated when the electronic components operate is unable to be dissipated effectively. Thus, the electronic components may be damaged owing to excessive heat. The electronic components are then unable to achieve predetermined working performance, and that requires to be improved.

A vapor chamber unit 1 is developed. Referring to FIGS. 1, 1A and 2, the conventional vapor chamber unit 1 includes a base plate 11, a heat dissipation net 12 disposed on the base plate 11, a cover 13 engaging with the base plate 11, and an accommodation area a defined between the base plate 11 and the cover 13 and filled with working fluid 14. The accommodation area a is adapted to accommodate the heat dissipation net 12. The heat dissipation net 12 has a plurality of metal wires 121 crossing each other, with a plurality of pores 122 formed between the metal wires 121. After the shape of the heat dissipation net 12 is adjusted according to the shape of the base plate 11 or the shape of the installed position, the heat dissipation net 12 is disposed on the base plate 11 by hot pressing. When the vapor chamber unit 1 is installed on an electronic product (not shown) to allow a surface of the vapor chamber unit 1 to contact with the electronic product, heat generated by the electronic product can be absorbed by the working fluid 14 filled in the vapor chamber unit 1. The working fluid 14 is then vaporized and moves from a high temperature area to a low temperature area though the pores 122 and the metal wires 121 to thereby execute the heat conduction operation, reduce a temperature of the electronic product, and maintain a smooth operation of the electronic product.

However, the metal wires 121 of the heat dissipation net 12 will be easily deformed and stuck on the base plate 11 when the heat dissipation net 12 is fixed on the base plate 11 by hot pressing, and that will affect a capillary action of the heat dissipation net 12 and obstruct the conduction path of the vaporized working fluid 14. Thus, the heat dissipation efficiency is poor. In other words, the vaporized working fluid 14 is unable to move from a high temperature area to a low temperature area and execute the heat conduction through the deformed heat dissipation net 12 after absorbing the heat because the capillary action of the heat dissipation net 12 is damaged. That requires to be improved.

### SUMMARY OF THE INVENTION

The object of this invention is to provide a heat dissipation net adapted to be disposed on a vapor chamber unit and capable of facilitating quick heat conduction and increasing heat dissipation efficiency.

The heat dissipation net is adapted to be disposed on a vapor chamber unit. The vapor chamber unit includes a base plate on which the heat dissipation net is disposed, a cover engaging with the base plate, and an accommodation area defined between the base plate and the cover for accommodating the heat dissipation net. The accommodation area is filled with working fluid. The heat dissipation net comprises a base net portion and a plurality of conduction units integrally formed on the base net portion. The base net portion is formed by a plurality of metal wires weaving together, with a plurality of pores formed between the metal wires to thereby assume a level arrangement. Each conduction unit has a protruding area, a recessed area, and a curved section formed between the protruding area and the recessed area. The protruding area and the base plate are spaced apart to form a space between the protruding area and the base plate when the heat dissipation net is disposed inside the accommodation area. Hence, the existence of the recessed area and the curved section prevents the base net portion from being unduly pressed and stuck on the base plate to thereby improve a capillary action of the heat dissipation net. The space facilitates the quick conduction of vaporized working fluid. Thus, the vaporized working fluid can be conducted quickly through the capillary action. The resistance caused when the condensed working fluid flows back and the cohesion of the condensed working fluid are reduced. The conduction of the working fluid is prevented from being obstructed. Hence, the heat dissipation efficiency is increased.

Preferably, the recessed area is enclosed by the protruding area.

Preferably, the recessed area is adjacently connected to the protruding area.

Preferably, the heat dissipation net defines a plurality of conduction groups spaced from each other. Each conduction group is formed by arranging a plurality of conduction units in alignment.

Preferably, the protruding area of each conduction unit has a rhombus profile to cause the recessed area enclosed by the protruding area to have a rhombus shape.

### BRIEF DESCRIPTION OF THE DRAWINGS

Exemplary embodiments of the invention are explained in the following with reference to drawings. The patent or application file contains at least one drawing executed in color. Copies of this patent or patent application publication with color drawings will be provided by the Office upon request and payment of the necessary fee.

FIG. 1 is a schematic view showing a conventional vapor chamber unit;

FIG. 1A is an enlarged view of the encircled portion 1A indicated in FIG. 1;

FIG. 2 is a cross-sectional view showing the conventional vapor chamber unit as seen along the line A-A of FIG. 1A;

FIG. 3 is a schematic view showing a first preferred embodiment of this invention;

FIG. 3A is an enlarged view of the encircled portion 3A indicated in FIG. 3;

FIG. 4 is a cross-sectional view showing the first preferred embodiment as seen along the line B-B of FIG. 3;

FIG. 5 is a schematic view showing a variation of the first preferred embodiment of this invention characterized by two spaced conduction groups;

FIG. 6 is a schematic view showing a second preferred embodiment of this invention characterized by the protruding area is adjacently connected to the recessed area;

FIG. 6A is an enlarged view of the encircled portion 6A indicated in FIG. 6;

FIG. 7 is a cross-sectional view showing the second preferred embodiment as seen along the line C-C of FIG. 6; and

FIG. 8 is an enlarged and graphical illustration showing conduction units of this invention under a microscope.

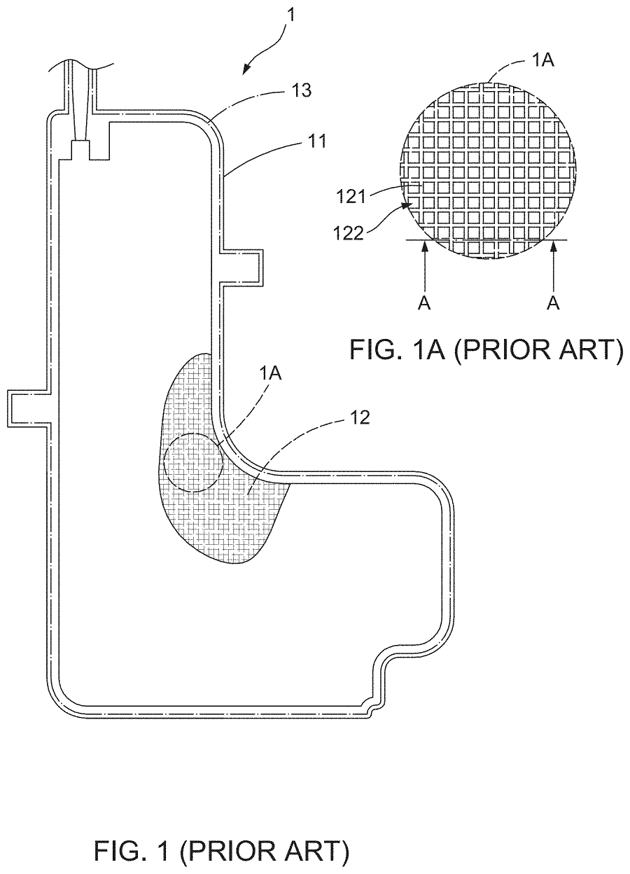

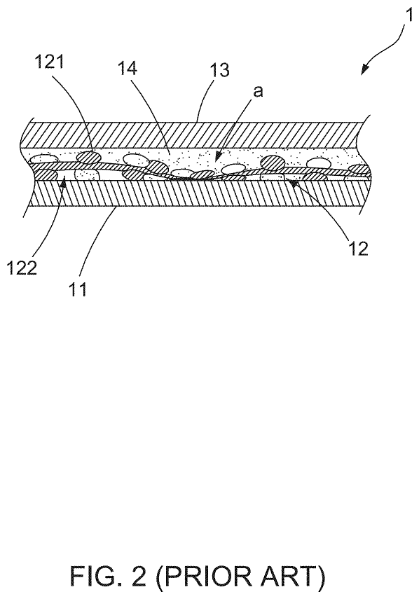

### DETAILED DESCRIPTION OF THE PREFERRED EMBODIMENTS

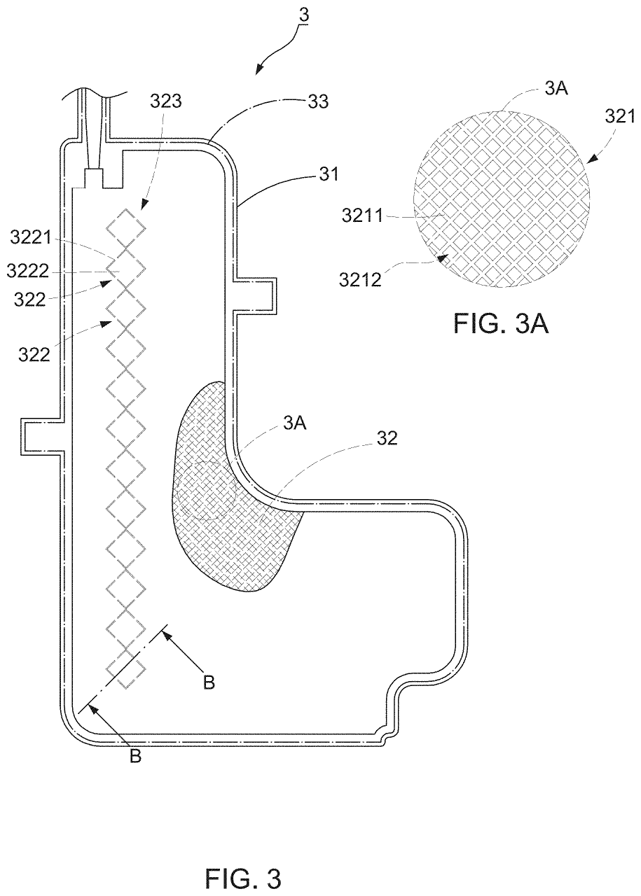

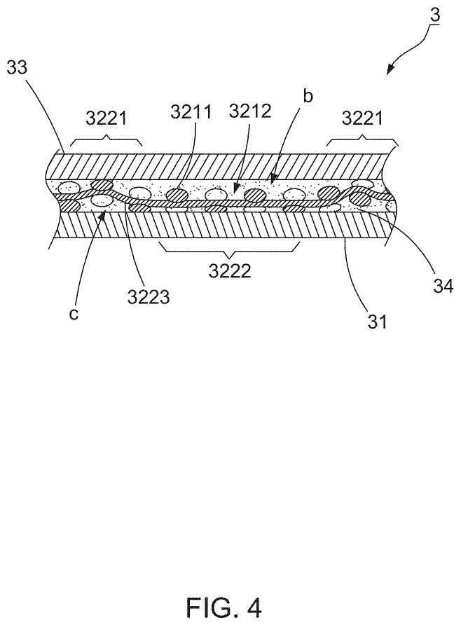

Referring to FIG. 3 and FIG. 4, a first preferred embodiment of a heat dissipation net 32 is disclosed. The heat dissipation net 32 is adapted to be disposed on a vapor chamber unit 3. The vapor chamber unit 3 includes a base plate 31 on which the heat dissipation net 32 is disposed, a cover 33 engaging with the base plate 31, and an accommodation area b defined between the base plate 31 and the cover 33. The accommodation area b is adapted to accommodate the heat dissipation net 32 and filled with working fluid 34. After the base plate 31 and the cover 33 are engaged together, the accommodation area b is vacuum pumped.

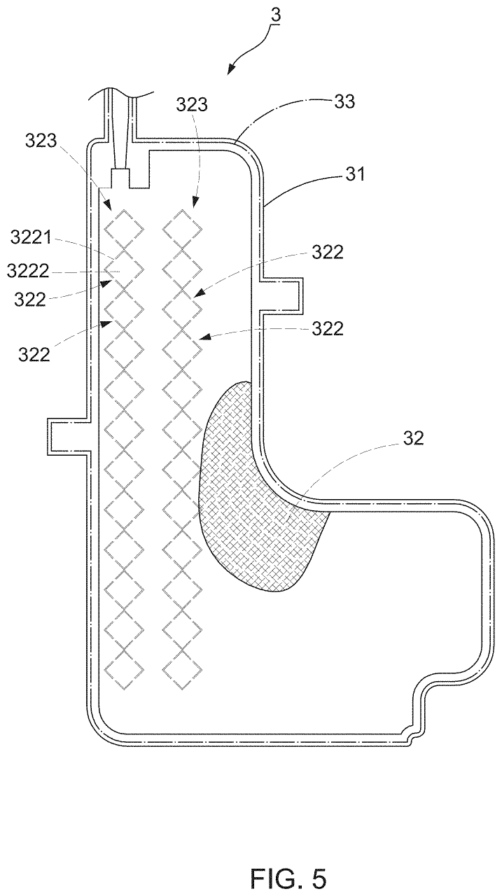

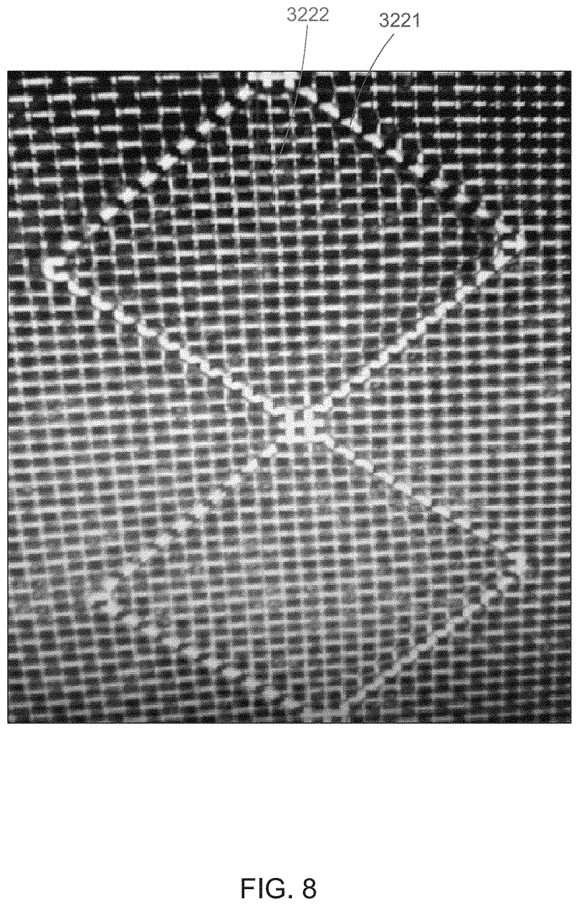

Referring to FIGS. 3, 3A and 4, the heat dissipation set 32 comprises a base net portion 321 and a plurality of conduction units 322 integrally formed on the base net portion 321. The base net portion 321 is formed by a plurality of metal wires 3211 crossing each other, with a plurality of pores 3212 formed between the metal wires 3211 to thereby assume a level arrangement. Each conduction unit 322 has a protruding area 3221 different from the level arrangement of the base net portion 321, a recessed area 3222 enclosed by the protruding area 3221, and a curved section 3223 formed between the protruding area 3221 and the recessed area 3222 to make a cross-sectional view of the conduction unit 322 to be a wave shape as shown in FIG. 4. In this preferred embodiment, the protruding area 3221 of each conduction unit 322 has a rhombus profile to cause the recessed area 3222 enclosed by the protruding area 3221 to have a rhombus shape as shown in FIG. 8. When the heat dissipation net 32 is disposed on the base plate 31, the protruding area 3221 and the base plate 31 are spaced apart to form a space c between the protruding area 3221 and the base plate 31 to thereby prevent the base net portion 321 from being unduly pressed and stuck on the base plate 31. Referring to FIG. 5, a variation of the first preferred embodiment is shown. In this variation, the heat dissipation net 32 defines a plurality of conduction groups 323 spaced from each other. Each conduction group 323 is formed by arranging a plurality of conduction units 322 in alignment. The shape and formed location of the conduction units 322 on the base net portion 321 can be adjusted according to needs to thereby satisfy different requirements of heat dissipation. Meanwhile, the shape of the heat dissipation net 32 can be adjusted according to the shape of the base plate 31 or the installed position to allow the heat dissipation net 32 to fit the base plate 31 properly. In this preferred embodiment, the metal wires 3211 are made of a wire material with high thermal conductivity. Hence, when the heat dissipation net 32 is fixed on the base plate 31 by hot pressing, the recessed area 3222 and the curved section 3223 can push the base plate 31 to further support the base net portion 321 and prevent the base net portion 321 from unduly pressed and stuck on the base plate 31. Thus, the metal wires 3211 of the base net portion 321 will not be damaged or deformed caused by unduly pressing.

Referring to FIGS. 3, 3A and 4, when using the vapor chamber unit 3, the vapor chamber unit 3 is disposed on an electronic product (not shown) to allow a surface of the base plate 31 of the vapor chamber unit 3 to contact with the electronic product. The vapor chamber unit 3 can be installed on an area of the electronic product that generates more heat. When the electronic product operates to generate heat, the working fluid 34 filled in the vapor chamber unit 3 is then vaporized after absorbing the heat of the electronic product. The vaporized working fluid 34 then moves from a high temperature area to a low temperature area through the pores 3212 and the metal wires 3211 to thereby conduct and dissipate the heat quickly. Meanwhile, the existence of the recessed area 3222 and the curved section 3223 prevents the base net portion 321 from unduly pressed and stuck on the base plate 31 to thereby improve a capillary action of the heat dissipation net 32. The space c formed between each protruding area 3221 and the base plate 31 facilitates the quick conduction of the vaporized working fluid 34. The space c enlarges the conduction path of the working fluid 34, provides enough room for dissipating the heat, and prevents the conduction of the working fluid 34 from being obstructed. The vaporized working fluid 34 then can condense into liquid when arriving the low temperature area and flow back smoothly to the high temperature area. Unduly accumulation of the vaporized working fluid 34 after the working fluid 34 absorbs the heat is prevented. Further, the condensed working fluid 34 can flow back from the low temperature area to the high temperature rapidly. The resistance caused when the condensed working fluid 34 flows back and the cohesion of the condensed working fluid 34 are reduced. Thus, the circulation of the working fluid 34 can effectively conduct the heat of the electronic product outwards and prevent the electronic product from crashing or damaging caused by excessive heat to thereby increase the heat dissipation efficiency.

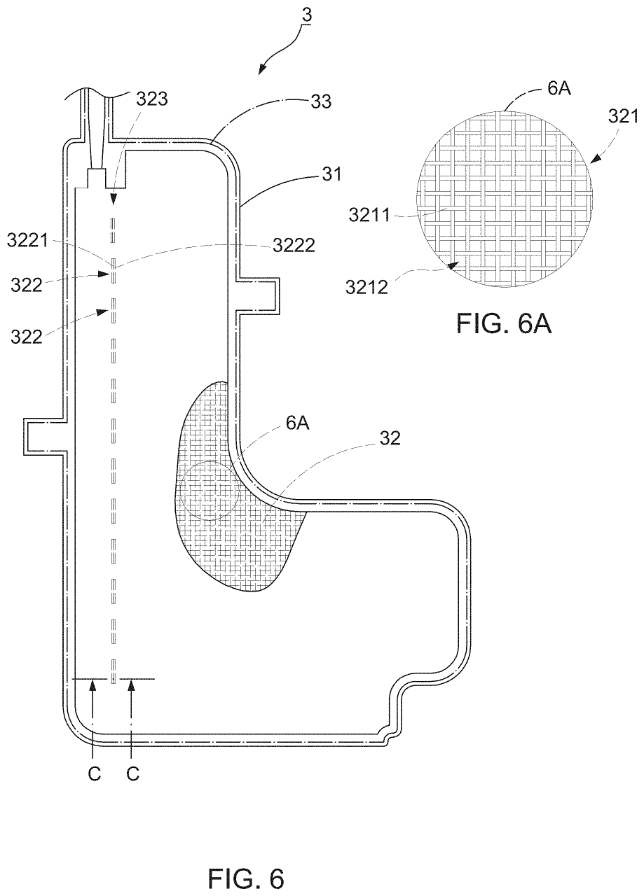

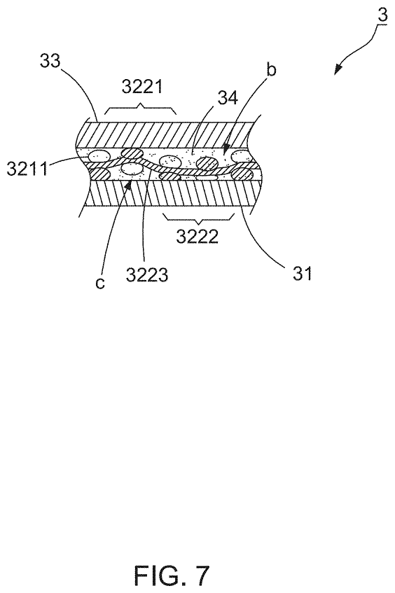

Referring to FIGS. 6, 6A and 7 show a second preferred embodiment of the heat dissipation net 32 of this invention. The correlated elements and the concatenation of elements, the operation and objectives of the second preferred embodiment are the same as those of the first preferred embodiment. This embodiment is characterized in that the recessed area 3222 is adjacently connected to the protruding area 3221. Hence, the correlated disposition between the protruding area 3221 and the recessed area 3222 can be adjusted according to needs to thereby increase the heat dissipation efficiency.

To sum up, the heat dissipation net of this invention takes advantages of the recessed area and the curved section to prevent the base net portion from unduly pressed and stuck on the base plate to improve the capillary action of the heat dissipation net and prevent the conduction of the working fluid from being obstructed. Meanwhile, the space formed between each protruding area and the base plate enlarges the conduction path of the working fluid, provides enough room for dissipating the heat, and facilitates the quick conduction of the working fluid. Thus, the working fluid will not accumulate unduly. The heat conduction is accelerated and the heat dissipation efficiency is increased.

While the embodiments of this invention are shown and described, it is understood that further variations and modifications may be made without departing from the scope of this invention.

What is claimed is:

1. A heat dissipation net adapted to be disposed on a vapor chamber unit which includes a base plate on which said heat dissipation net is disposed, a cover engaging with said base plate, and an accommodation area defined between said base plate and said cover and adapted to accommodate said heat dissipation net, with said accommodation area filled with working fluid, said heat dissipation net comprising:
a base net portion formed by a plurality of metal wires crossing each other, with a plurality of pores formed between said plurality of metal wires to thereby assume a level arrangement; and
a plurality of conduction units integrally formed on said base net portion, wherein each of said plurality of conduction units includes a protruding area different from said level arrangement, a recessed area enclosed by said protruding area, and a curved section formed between said protruding area and said recessed area, said protruding area and said base plate being spaced apart to form a space between said protruding area and said base plate when said heat dissipation net is disposed inside said accommodation area.

2. The heat dissipation net according to claim 1, wherein said heat dissipation net defines a plurality of conduction groups spaced from each other, each of said plurality of conduction groups being formed by arranging said plurality of conduction units in alignment.

3. The heat dissipation net according to claim 1, wherein said protruding area of each of said plurality of conduction units has a rhombus profile to cause said recessed area enclosed by said protruding area to have a rhombus shape.

4. The heat dissipation net according to claim 2, wherein said protruding area of each of said plurality of conduction units has a rhombus profile to cause said recessed area enclosed by said protruding area to have a rhombus shape.

5. A heat dissipation net adapted to be disposed on a vapor chamber unit which includes a base plate on which said heat dissipation net is disposed, a cover engaging with said base plate, and an accommodation area defined between said base plate and said cover and adapted to accommodate said heat dissipation net, with said accommodation area filled with working fluid, said heat dissipation net comprising:
a base net portion formed by a plurality of metal wires crossing each other, with a plurality of pores formed between said plurality of metal wires to thereby assume a level arrangement; and
a plurality of conduction units integrally formed on said base net portion, wherein each of said plurality of conduction units includes a protruding area different from said level arrangement, a recessed area adjacently connected to said protruding area, and a curved section formed between said protruding area and said recessed area, said protruding area and said base plate being spaced apart to form a space between said protruding area and said base plate when said heat dissipation net is disposed inside said accommodation area.

6. The heat dissipation net according to claim 5, wherein said heat dissipation net defines a plurality of conduction groups spaced from each other, each of said plurality of conduction groups being formed by arranging said plurality of conduction units in alignment.
